(19) United States
(12) Patent Application Publication
(10) Pub. No.: US 2026/0068093 A1
(43) Pub. Date: Mar. 5, 2026

(54) TECHNIQUES FOR TEMPERATURE STABILIZING AT LEAST ONE DEVICE

(71) Applicant: Honeywell International Inc., Charlotte, NC (US)

(72) Inventors: Argyrios Dellis, Plymouth, MN (US); Chad Fertig, Roseville, MN (US); Luke Horstman, Saint Louis Park, MN (US); Karl D. Nelson, Plymouth, MN (US); Chad Hoyt, Roseville, MN (US)

(73) Assignee: Honeywell International Inc., Charlotte, NC (US)

(21) Appl. No.: 18/822,837

(22) Filed: Sep. 3, 2024

(51) Int. Cl. H05K 7/20; F25B 21/02; F28F 13/00; G05D 23/185

(52) U.S. Cl. CPC H05K 7/2039; F25B 21/02; G05D 23/1852; G05D 23/1854; F25B 2321/0212; F28F 2013/008

(57) ABSTRACT

A heater is configured to raise a temperature of the device(s) when the temperature is less than a first temperature threshold level. When the temperature is not less than the first temperature threshold level, then the heater is configured to be turned off, and thus provides no heating. A thermally activated actuator is configured to close a thermally activated switch when a temperature of an environment and/or the thermally activated actuator exceeds a second temperature threshold level. In such case, the thermally activated actuator thermally couples the device(s) to a thermal electric cooler. The thermal electric cooler reduces the temperature of the device(s) by drawing heat from the device(s). The thermally activated actuator is configured to open the thermally activated switch when the temperature of the environment and/or the thermally activated actuator is less than the second temperature threshold level; the thermal electric cooler no longer cools the device(s).

### BACKGROUND

An atomic sensor uses laser(s) to generate an optical signal at a specific frequency to probe atoms. A laser is sensitive to variations in temperature. A temperature change can cause the specific frequency to change. If the specific frequency shifts, the atomic sensor may be rendered inoperable.

### SUMMARY

In some aspects, the techniques described herein relate to an apparatus which temperature stabilizes at least one device, the apparatus including: a package including a package thermal conductor; a thermally activated switch including: a thermal electric cooler (TEC) including a first TEC surface thermally connected to the package thermal conductor, and a second TEC surface; a thermally activated actuator (TAA); and a thermal conductor (TC) including a TC surface; the at least one device on and/or in the thermal conductor; and a temperature compensation system on and/or in the thermal conductor, wherein the temperature compensation system includes at least one temperature sensor, a heater, and a processing circuitry, and wherein the at least one temperature sensor each of which is in the package or thermally coupled to the package thermal conductor, and wherein the at least one temperature sensor is configured to measure a first temperature that is a function of (x) a temperature of an interior environment in the package and/or (y) a temperature of the package; wherein the processing circuitry is configured to cause the heater to heat the at least one device when the first temperature is below a first temperature threshold level and to not heat the at least one device when the first temperature is above the first temperature threshold level; wherein the thermally activated switch is configured to (a) thermally couple the thermal conductor and the thermal electric cooler when the first temperature and/or a temperature of the thermally activated actuator exceeds a second temperature threshold level and (b) thermally decouple the thermal conductor and the thermal electric cooler when the first temperature and/or the temperature of the thermally activated actuator is less than the second temperature threshold level; wherein the second temperature threshold level is greater than the first temperature threshold level.

In some aspects, the techniques described herein relate to a method for temperature stabilizing at least one device, the method including: receiving a first temperature, wherein the first temperature is a function of (x) a temperature of an interior environment in a package and/or (y) a temperature of a package, wherein the package includes a package thermal conductor, and wherein the at least one device is on and/or in a thermal conductor; determining whether the first temperature is less than a first temperature threshold level; determining that the first temperature is less than the first temperature threshold level, then turning on a heater; determining that the first temperature is greater than the first temperature threshold level, then: turning off the heater; thermally coupling the thermal conductor and a thermal electric cooler when the first temperature is greater than a second temperature threshold level, then, wherein a thermally activated switch includes: the thermal electric cooler (TEC) including a first TEC surface thermally connected to the package thermal conductor, and a second TEC surface; a thermally activated actuator (TAA); and the thermal conductor (TC) including a TC surface; and thermally decoupling the thermal conductor and the thermal electric cooler when the first temperature and/or the temperature of the thermally activated actuator is less than the second temperature threshold level; wherein the second temperature threshold level is greater than the first temperature threshold level.

In some aspects, the techniques described herein relate to an apparatus for controlling a temperature of at least one component of an atomic sensor, the apparatus including: a package including a package thermal conductor; a thermal electric cooler (TEC) including a first TEC surface, thermally connected to the package thermal conductor, and a second TEC surface; a thermally activated actuator (TAA); a thermal conductor (TC) including a TC surface; the at least one component on the thermal conductor; and a heater on or in the thermal conductor and configured to heat the thermal conductor and the at least one component when a temperature of the thermal conductor and/or the temperature at least one of the at least one component falls below a first temperature threshold level; wherein the thermally activated actuator is configured to change position based on a temperature of the thermally activated actuator to form a thermal connection between a surface of the thermal conductor and the second TEC surface when the temperature of the thermally activated actuator exceeds a second temperature threshold level so that the TEC cools the thermal conductor and the at least one component and to break off thermal contact between the surface of the thermal conductor and the second TEC surface when the temperature of the thermally activated actuator falls below a third temperature threshold level.

### BRIEF DESCRIPTION OF THE DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 illustrates a block diagram of one embodiment of a thermally compensated apparatus including a thermally activated actuator implemented according to embodiments of the invention; and

FIG. 2 illustrates a flow diagram of one embodiment of a method of temperature stabilizing device(s).

In accordance with common practice, the various described features are not drawn to scale but are drawn to emphasize specific features relevant to the exemplary embodiments. Reference characters denote like elements throughout figures and text.

### DETAILED DESCRIPTION

In the following detailed description, reference is made to the accompanying drawings that form a part hereof, and in which is shown by way of illustration specific illustrative embodiments. However, it is to be understood that other embodiments may be utilized, and that structural, mechanical, and/or electrical changes may be made. Furthermore, each method presented in the drawing figures and the specification is not to be construed as limiting the order in which the individual steps may be performed. The following detailed description is not to be taken in a limiting sense.

An apparatus, such as atomic sensor, with reduced size, weight, and power (SWaP), operating in environments having a wide range of temperatures, require techniques to stabilize the temperature of device(s) of the apparatus with reduced power consumption as compared to existing methods. Embodiments of the invention provide a technological improvement to temperature stabilize device(s) in a small volume over a wide temperature range, e.g., −55 degrees C. to 105 degrees C. while consuming less power to do so. Optionally, embodiments of the invention stabilize the temperature of the device(s) within one degree Kelvin, e.g., within a few milliKelvins. Optionally, the device(s) may be laser(s) in an apparatus that is a compact atomic sensor.

Embodiments of the invention may utilize the following techniques. A heater, e.g., a resistive heater, is configured to raise a temperature of the device(s) when the temperature is less than a first temperature threshold level. When the temperature is greater than the first or a third temperature threshold level, then the heater is configured to be turned off, and thus provides no heating.

A thermally activated actuator is configured to close a thermally activated switch when a first temperature exceeds the first, a second, or the third temperature threshold level; such first temperature is a function of (x) a temperature of an interior environment in the package and/or (y) a temperature of a package, e.g., the temperature of the interior environment in the package, the temperature of the package, an average of the temperature of the interior environment and the temperature of the package, or any function of the two temperatures. The interior environment is an environment about the device(s) in a package and completely or partially surrounding the device(s). In such case, the thermally activated actuator thermally couples the device(s) (e.g., a thermal conductor on and/or in which the device(s) reside) to a thermal electric cooler. The thermal electric cooler reduces the temperature of the device(s) by drawing heat from the device(s), e.g., the thermal conductor.

The thermally activated actuator is configured to open the thermally activated switch when the first temperature is less than the first, the second, the third, or a fourth temperature threshold level. Thus, the thermally activated actuator no longer thermally couples to the device(s) (e.g., the thermal conductor on and/or in which the device(s) resides) to the thermal electric cooler; thus, the thermal electric cooler can no longer reduce temperature of the device(s), e.g., such thermal conductor.

The (a) activation and deactivation of the heater and (b) closing and opening the thermally activated switch with the thermally activated actuator are illustrated, in part, using hysteresis to avoid rapid periodic activation and deactivation and/or rapid periodic closing and opening of the thermally activated switch with the thermally activated actuator. However, hysteresis need not be used for (a) and/or (b), e.g., by using a single temperature threshold level each for (a) and/or (b).

For pedagogical purposes, the device(s) will be illustrated as at least one laser (laser(s)). However, the device(s) may be any other device(s), e.g., at least one of an electronic or electric device(s). Optionally, the device(s) includes at least one of: integrated circuit(s), source(s) of electromagnetic energy, mechanical structure(s) (for example, scaffolding in the atomic sensor), an atomic reservoir, and optics.

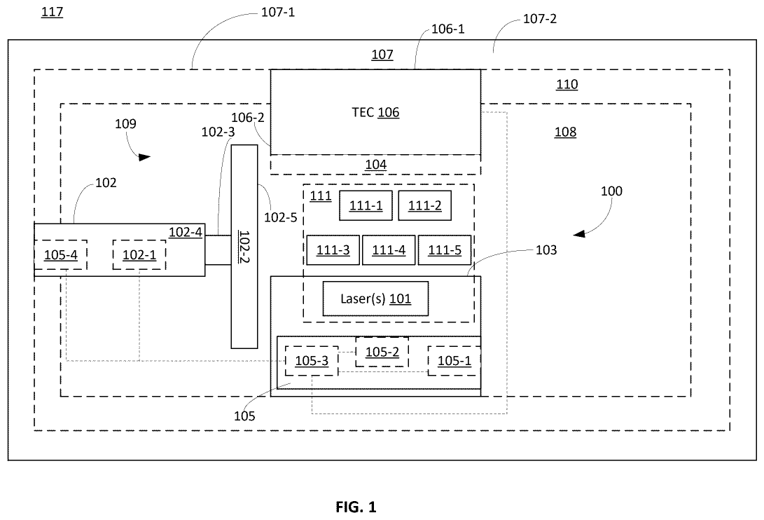

FIG. 1 illustrates a block diagram of one embodiment of a thermally compensated apparatus including a thermally activated actuator implemented according to embodiments of the invention (or thermally compensated apparatus) 100. The thermally compensated apparatus 100 includes the laser(s) 101, the thermally activated actuator 102, a first thermal conductor 103, a temperature compensation system 105, the thermal electric cooler (TEC) 106, and a package 107.

Optionally, thermal conductors described herein may be metal or metal alloys. Optionally, an interior surface 107-1 of the package 107, e.g., a package thermal conductor 107-2, the is partially or wholly covered with a package thermal insulator 110. Optionally, the package includes, e.g., is formed by, the package thermal conductor 107-2.

Optionally, the laser(s) 101 are part of an optional atomic sensor 111. The atomic sensor 111 optionally further includes at least one of: integrated circuit(s) 111-1, source(s) of electromagnetic energy 111-2, mechanical structure(s) 111-3 (for example, scaffolding in the atomic sensor), an atomic reservoir 111-4, and optics 111-5.

The thermal electric cooler 106 includes a first TEC surface 106-1 thermally connected or coupled to the package thermal conductor 107-2, and a second TEC surface 106-2. The thermal electric cooler 106 is configured to generate a temperature less than the third and fourth temperature threshold levels or between the third and fourth temperature threshold levels. The thermal electric cooler 106 is thermally coupled to an optional second thermal conductor 104. The thermal electric cooler 106 is configured to have one of its surfaces thermally coupled or contacting the interior surface 107-1 of the package 107.

The package 107 surrounds all or part of the thermally compensated apparatus 100. Optionally, the package 107 is formed from a thermal conductor and/or a thermal insulator. Each of the laser(s) 101, and optionally one or more components of the temperature compensation system 105, are mounted on and/or in the first thermal conductor 103.

Optionally, the temperature compensation system 105 includes at least one temperature sensor, a heater 105-2, and the processing system (or processing circuitry) 105-3. Optionally, each of the at least one temperature sensor and the heater 105-2 is communicatively coupled to the processing system 105-3. Optionally, the heater 105-2 is a resistive heater. Optionally, each of the at least one temperature sensor is a thermistor, a temperature detector, a thermocouple, or any other type of temperature sensor.

The at least one temperature sensor includes at a first temperature sensor 105-1 and/or a second temperature sensor 105-4. The optional first temperature sensor 105-1 is communicatively coupled to the processing system 105-3. The optional first temperature sensor 105-1 is configured to measure the temperature of an interior environment 108 in the package 107 (or interior environmental temperature). The interior environment 108, for example, is around the thermally compensated apparatus 100. Optionally, the temperature of the interior environmental 108 may be deemed to be a temperature of the thermal conductor 103 and/or a temperature of at least one of the laser(s) 101.

The optional second temperature sensor 102-5 is configured to thermally contact the package 107, e.g., an inner surface 107-1 of the package 107. The optional second temperature sensor 102-5 is configured to measure the temperature of the package 107, and thus indirectly the temperature of an exterior environment 117 around the package. The optional second temperature sensor 102-5 is communicatively coupled to the processing system 105-3. For pedagogical purposes, the optional second temperature sensor 102-5 is illustrated as being part of the thermally activated actuator 102, e.g., in a third portion 102-4 therein; however, the optional second temperature sensor 102-5 may be located elsewhere so long as it is configured to measure the temperature of the package 107. Thus, embodiments of the invention include at least one temperature sensor configured to measure at least one of: a temperature of an interior environment 108 in the package 107 and a temperature of the package 107.

The following exemplifies operation of the thermally compensated apparatus 100 when no hysteresis is used. An alternative operation the thermally compensated apparatus 100 using hysteresis is described elsewhere herein. If a first temperature is less than a first threshold temperature level T1, then the processing system 105-3 is configured to activate the heater 105-2 (i.e., to cause the heater to generate heat). The first temperature is a function of (x) a temperature of an interior environment in the package and/or (y) a temperature of a package, e.g., the temperature of the interior environment in the package, the temperature of the package, an average of the temperature of the interior environment and the temperature of the package, or any function of the two temperatures. If the first temperature is not less than a first threshold temperature (T1), then the processing system 105-3 is configured to deactivate the heater 105-2 (i.e., to cause the heater to not generate heat).

The thermally activated actuator 102 is a mechanical device a portion of which moves as a function of the environmental temperature and/or the temperature of the thermally activated actuator 102. Optionally, the moving portion is driven by a component, e.g., a motor (for example, an electric motor), a wax motor, or bimetallic switch, as a function of the first temperature and/or a temperature of the thermally activated actuator. Optionally, the third portion 102-4 includes a thermal conductor thermally coupling the component, e.g., the wax motor or the bimetallic switch, driving the moving portion and the interior surface 107-1 of the package 107.

The combination of the thermally activated actuator 102, the first thermal conductor 103, and TEC 106 (and optionally the optional second thermal conductor 104) is a thermally activated switch 109. When the first temperature and/or the temperature of the thermally activated actuator (FT and/or TAAT) 102 is greater than a second temperature threshold level (T2), then a portion of the thermally activated actuator 102 moves to close the thermally activated switch 109 permitting heat to flow from the first thermal conductor 103 through at least a portion of the thermally activated actuator 102, optionally through the optional second thermal conductor 104, to the thermal electric cooler 106.¹ Optionally, the TEC 106 is activated, e.g., begins cooling. As a result, a temperature of the first thermal conductor 103, and thus the laser(s) 101 and the interior environment 108, are reduced. ¹ Thus, optionally, a thermal connection is formed between, e.g., a surface 102-5 of, the first thermal conductor and, e.g., a second surface 106-2 of, the thermal electric cooler 106.

When the environmental temperature and/or the temperature of the thermally activated actuator 102 is less than the second temperature threshold level (T2), then a portion of the thermally activated actuator 102 moves to open the thermally activated switch 109; as a result, heat cannot dissipate to the thermal electric cooler 106, and the temperature of the first thermal conductor 103, and thus the laser(s) 101 and the environment 108 can increase, e.g., due to heat dissipated by the laser(s) 101 or other component(s) in the thermally compensated apparatus 100. Optionally, the TEC 106 is deactivated, e.g., ceases cooling. Optionally, the processing system 105-3 is communicatively coupled to the thermal electric cooler 106. In such case, optionally, the processing system 105-3 is configured to activate and deactivate the thermal electric cooler 106 pursuant to techniques described elsewhere herein.

The second temperature threshold level is greater than the fourth temperature threshold level. Optionally, the third temperature threshold level is greater than or equal to the fourth temperature threshold level. The first temperature threshold level is less than the third temperature threshold level. Optionally, the first and the second temperature levels are equal. Optionally, the third temperature and the fourth temperature threshold levels are equal.

Optionally, the thermally activated actuator 102 includes the motor 102-1 described elsewhere herein. In such case, the motor 102-1 is communicatively coupled to a processing system (e.g., the processing system 105-3), and when the first temperature is:
(a) greater than the second temperature threshold level, then the motor 102-1 moves a portion of the thermally activated actuator 102 to close the thermally activated switch 109 (with the result described elsewhere herein); and
(b) is less than the fourth temperature threshold level, then the motor 102-1 moves a portion of the thermally activated actuator 102 to open the thermally activated switch 109 (with the result described elsewhere herein).

FIG. 1 illustrates that the motor 102-1 is communicatively coupled to the processing system 105-3 of the temperature compensation system 105. However, in other embodiments, the motor may utilize a different processing system which may or may not be communicatively coupled to a temperature sensor other than the first temperature sensor 105-1 of the temperature compensation system 105. For example, the motor 102-1 may be communicatively coupled to another processing system located in and/or on the thermally activated actuator 102, e.g., in a third portion 102-4 thereof.

As illustrated in FIG. 1 for pedagogical purposes, the thermally activated actuator 102 optionally includes a first portion 102-2, a second portion 102-3, and the third portion 102-4. The first portion 102-2 includes a thermal conductor configured to form a thermally conductive pathway (when the thermally activated switch 109 is activated) between the TEC 106 and the first thermal conductor 103. The second portion 102-3 is a thermal insulator. The third portion 102-4 is either a thermal insulator or a thermal conductor. Optionally, the third portion 102-4 is (a) a thermal conductor when contacting the interior surface 107-1 of the package 107 (as illustrated for pedagogical purposes in FIG. 1) or (b) a thermal insulator when contacting the optional package thermal insulator 110. The thermally activated actuator 102, however, may be implemented in other ways.

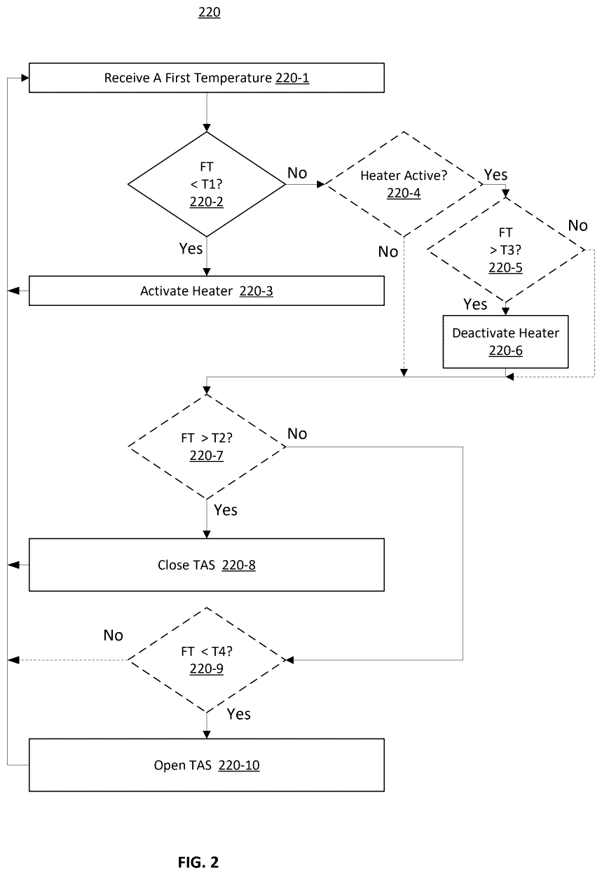

FIG. 2 illustrates a flow diagram of one embodiment of a method 220 of temperature stabilizing device(s). Exemplary method 220 may be implemented by all or part of thermally compensated apparatus 100 illustrated in FIG. 1. Optionally, the thermally compensated apparatus 100 illustrated in FIG. 1 may operate according to the method 220. To the extent the methods herein are described herein as being implemented with the apparatus illustrated in FIG. 1, it is to be understood that other embodiments can be implemented in other ways. Techniques described with respect to the embodiments illustrated by FIG. 1 may be applicable to the method 220.

The blocks of the flow diagrams herein have been arranged in a generally sequential manner for ease of explanation; however, it is to be understood that this arrangement is merely exemplary, and it should be recognized that the processing associated with the methods (and the blocks shown in the Figures) can occur in a different order (for example, where at least some of the processing associated with the blocks is performed in parallel and/or in an event-driven manner).

Method 220 illustrates optional blocks which implement hysteresis for both controlling heater activation and deactivation, and opening and closing of the thermally activated switch. However, method 220, can be implemented without one or both hysteresis by not including certain optional blocks.

In block 220-1, a first temperature (FT) is received, e.g., by at least one temperature sensor. The first temperature is described elsewhere herein. In block 220-2, whether the first temperature is less than a first temperature threshold level is determined.

If the first temperature is less than the first temperature threshold level, then in block 220-3, activate, e.g., turn on the heater. If the first temperature is not less than the first temperature threshold level, then proceed to either optional block 220-4, optional block 220-5, or block 220-6. In optional block 220-4, whether the heater is active, e.g., the heater is turned on, is determined. If the heater is determined not to be active, e.g. the heater is turned off, then proceed to block 220-7.

If the heater is determined to be active, then proceed to either optional block 220-5 or block 220-6. In optional block 220-5, whether the first temperature is greater than a third temperature threshold level is determined. If the first temperature is not greater than the third temperature threshold level, then proceed to either optional block 220-7, block 220-8, or block 220-10. If the first temperature level is greater than the third temperature threshold level, then proceed to block 220-6. In block 220-6, the heater is deactivated, e.g., the heater is turned off. After block 220-6, proceed to optional block 220-7, block 220-8, or block 220-10.

In optional block 220-7, whether the first temperature is greater than a second temperature threshold level is determined. If the first temperature and/or the temperature of the thermally activated actuator is greater than the second temperature threshold level, then in block 220-8, the thermally activated switch (TAS) is closed by the thermally activated actuator, i.e., the thermal conductor is thermally coupled to the thermal electric cooler; optionally the thermal electric cooler is activated when the thermally activated switch is closed, e.g., when the first temperature and/or the temperature of the thermally activated actuator is greater than the second temperature threshold level. After block 220-8, proceed to either block 220-1 or block 220-2.

If the first temperature and/or the temperature of the thermally activated actuator is not greater than the second temperature threshold level, then in optional block 220-9, whether the first temperature is less than a fourth temperature threshold level is determined. If the first temperature and/or the temperature of the thermally activated actuator is less than the fourth temperature threshold level, then in block 220-10 the thermally activated switch is opened by the thermally activated actuator as described elsewhere herein, i.e., the thermal conductor is thermally decoupled from the thermal electric cooler; optionally the thermal electric cooler is deactivated when the thermally activated switch is opened, e.g., when the first temperature and/or the temperature of the thermally activated actuator is less than the fourth temperature threshold level. After block 220-10, proceed to either block 220-1 or block 220-2. Optionally, if the first temperature is not less than the third temperature threshold level, then proceed to either block 220-1 or block 220-2.

While the present teachings have been illustrated with respect to one or more implementations, alterations and/or modifications can be made to the illustrated examples without departing from the scope of the appended claims. In addition, while a particular feature of the present disclosure may have been described with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and/or the claims, such terms are intended to be inclusive in a manner similar to the term “comprising.” The term “at least one of” is used to mean one or more of the listed items can be selected. As used herein, the term “one or more of” with respect to a listing of items such as, for example, A and B or A and/or B, means A alone, B alone, or A and B. The term “at least one of” is used to mean one or more of the listed items can be selected.

A processing system may include processor circuitry coupled to memory circuitry. The processor circuitry described herein may include one or more microprocessors, microcontrollers, digital signal processing (DSP) elements, application-specific integrated circuits (ASICs), and/or field programmable gate arrays (FPGAs). In this exemplary embodiment, processor circuitry includes or functions with software programs, firmware, or other computer readable instructions for carrying out various process tasks, calculations, and control functions, used in the methods described herein. These instructions are typically tangibly embodied on any storage media (or computer readable medium) used for storage of computer readable instructions or data structures.

The memory circuitry described herein can be implemented with any available storage media (or computer readable medium) that can be accessed by a general purpose or special purpose computer or processor, or any programmable logic device. Suitable computer readable medium may include storage or memory media such as semiconductor, magnetic, and/or optical media. For example, computer readable media may include conventional hard disks, Compact Disk-Read Only Memory (CD-ROM), DVDs, volatile or non-volatile media such as Random Access Memory (RAM) (including, but not limited to, Dynamic Random Access Memory (DRAM)), Read Only Memory (ROM), Electrically Erasable Programmable ROM (EEPROM), and/or flash memory. Combinations of the above are also included within the scope of computer readable media.

Methods (or portions thereof) of the invention can be implemented in computer readable instructions, such as program modules or applications, which may be stored in the computer readable medium that is part of (optionally the memory circuitry) or communicatively coupled to the processing circuitry, and executed by the processing circuitry, optionally the processor circuitry. Generally, program modules or applications include routines, programs, objects, data components, data structures, algorithms, and the like, which perform particular tasks or implement particular abstract data types.

### Example Embodiments

Example 1 includes an apparatus which temperature stabilizes at least one device, the apparatus comprising: a package comprising a package thermal conductor; a thermally activated switch including: a thermal electric cooler (TEC) including a first TEC surface thermally connected to the package thermal conductor, and a second TEC surface; a thermally activated actuator (TAA); and a thermal conductor (TC) including a TC surface; the at least one device on and/or in the thermal conductor; and a temperature compensation system on and/or in the thermal conductor, wherein the temperature compensation system includes at least one temperature sensor, a heater, and a processing circuitry, and wherein the at least one temperature sensor each of which is in the package or thermally coupled to the package thermal conductor, and wherein the at least one temperature sensor is configured to measure a first temperature that is a function of (x) a temperature of an interior environment in the package and/or (y) a temperature of the package; wherein the processing circuitry is configured to cause the heater to heat the at least one device when the first temperature is below a first temperature threshold level and to not heat the at least one device when the first temperature is above the first temperature threshold level; wherein the thermally activated switch is configured to (a) thermally couple the thermal conductor and the thermal electric cooler when the first temperature and/or a temperature of the thermally activated actuator exceeds a second temperature threshold level and (b) thermally decouple the thermal conductor and the thermal electric cooler when the first temperature and/or the temperature of the thermally activated actuator is less than the second temperature threshold level; wherein the second temperature threshold level is greater than the first temperature threshold level.

Example 2 includes the apparatus of Example 1, wherein the at least one device comprises at least one laser.

Example 3 includes the apparatus of any of Examples 1-2, wherein the apparatus is an atomic sensor; wherein the at least one device comprises at least one of: at least one laser, at least one integrated circuit, at least one source of electromagnetic energy, a mechanical structure, an atomic reservoir, and optics.

Example 4 includes the apparatus of any of Examples 1-3, wherein the package further comprises a package thermal insulator partially or wholly covering an interior surface of the package thermal conductor.

Example 5 includes the apparatus of any of Examples 1-4, wherein the thermally activated actuator comprises at least one of a wax motor and a bimetallic strip; wherein the thermally activated switch performs thermal coupling and thermal decoupling based on the temperature of the thermally activated actuator.

Example 6 includes the apparatus of any of Examples 1-5, wherein the processing circuitry is further configured to activate the thermal electric cooler when the thermally activated switch thermally couples the thermal conductor and the thermal electric cooler; wherein the processing circuitry is further configured to deactivate the thermal electric cooler when the thermally activated switch thermally decouples the thermal conductor and the thermal electric cooler.

Example 7 includes the apparatus of any of Examples 1-6, wherein the thermally activated actuator comprises a first thermal conductor portion and a second thermal conductor portion which are thermally isolated from one another by a thermal insulator; wherein the first thermal conductor portion is thermally coupled to the package thermal conductor; wherein the second thermal conductor portion is configured to form a thermal connection between the TC surface and the second TEC surface.

Example 8 includes a method for temperature stabilizing at least one device, the method comprising: receiving a first temperature, wherein the first temperature is a function of (x) a temperature of an interior environment in a package and/or (y) a temperature of a package, wherein the package includes a package thermal conductor, and wherein the at least one device is on and/or in a thermal conductor; determining whether the first temperature is less than a first temperature threshold level; determining that the first temperature is less than the first temperature threshold level, then turning on a heater; determining that the first temperature is greater than the first temperature threshold level, then: turning off the heater; thermally coupling the thermal conductor and a thermal electric cooler when the first temperature is greater than a second temperature threshold level, then, wherein a thermally activated switch includes: the thermal electric cooler (TEC) including a first TEC surface thermally connected to the package thermal conductor, and a second TEC surface; a thermally activated actuator (TAA); and the thermal conductor (TC) including a TC surface; and thermally decoupling the thermal conductor and the thermal electric cooler when the first temperature and/or the temperature of the thermally activated actuator is less than the second temperature threshold level; wherein the second temperature threshold level is greater than the first temperature threshold level.

Example 9 includes the method of Example 8, wherein thermally coupling the thermal conductor and the thermal electric cooler further comprises determining whether the first temperature is greater than the second temperature threshold level; wherein the thermal coupling is only performed when the first temperature is greater than the second temperature threshold level.

Example 10 includes the method of any of Examples 8-9, wherein thermally decoupling the thermal conductor and the thermal electric cooler further comprises determining whether the first temperature is less than a third temperature threshold level; wherein the thermal decoupling is only performed when the first temperature is less than the third temperature threshold level.

Example 11 includes the method of any of Examples 8-10, wherein turning off the heater comprises: determining whether the heater is turned on; wherein the heater is turned off only when the heater is determined to be turned on.

Example 12 includes the method of any of Examples 8-11, wherein the thermally activated actuator comprises at least one of a wax motor and a bimetallic strip; wherein the thermal coupling and the thermal decoupling are performed based on the temperature of the thermally activated actuator.

Example 13 includes the method of any of Examples 8-12, wherein the thermally activated actuator comprises an electric motor; wherein the thermal coupling and the thermal decoupling are performed based on the first temperature.

Example 14 includes an apparatus for controlling a temperature of at least one component of an atomic sensor, the apparatus comprising: a package comprising a package thermal conductor; a thermal electric cooler (TEC) comprising a first TEC surface, thermally connected to the package thermal conductor, and a second TEC surface; a thermally activated actuator (TAA); a thermal conductor (TC) comprising a TC surface; the at least one component on the thermal conductor; and a heater on or in the thermal conductor and configured to heat the thermal conductor and the at least one component when a temperature of the thermal conductor and/or the temperature at least one of the at least one component falls below a first temperature threshold level; wherein the thermally activated actuator is configured to change position based on a temperature of the thermally activated actuator to form a thermal connection between a surface of the thermal conductor and the second TEC surface when the temperature of the thermally activated actuator exceeds a second temperature threshold level so that the TEC cools the thermal conductor and the at least one component and to break off thermal contact between the surface of the thermal conductor and the second TEC surface when the temperature of the thermally activated actuator falls below a third temperature threshold level.

Example 15 includes the apparatus of Example 14, wherein the at least one component consists of at least one laser.

Example 16 includes the apparatus of any of Examples 14-15, wherein the at least one component comprises at least one of: at least one laser, at least one integrated circuit, at least one source of electromagnetic energy, a mechanical structure, an atomic reservoir, and optics.

Example 17 includes the apparatus of any of Examples 14-16, wherein the package further comprises a thermal insulator in an interior of the package and surrounded by the package thermal conductor.

Example 18 includes the apparatus of any of Examples 14-17, wherein the thermally activated actuator comprises a first thermal conductor portion and a second thermal conductor portion which are thermally isolated from one another; wherein the first thermal conductor portion is thermally coupled to the package thermal conductor; wherein the package thermal conductor is exposed to exterior environmental temperature; wherein the second thermal conductor portion is configured to form the thermal connection between the surface of the thermal conductor and the second TEC surface.

Example 19 includes the apparatus of any of Examples 14-18, wherein the thermally activated actuator comprises a motor; wherein the thermally activated actuator is activated based on the temperature of the thermally activated actuator, and/or the temperature of the thermal conductor and/or the temperature of at least one of the at least one component.

Example 20 includes the apparatus of any of Examples 14-19, wherein the thermally activated actuator comprises at least one of a wax motor and a bimetallic strip; wherein the thermally activated actuator is activated based on the temperature of the thermally activated actuator.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. An apparatus which temperature stabilizes at least one device, the apparatus comprising:
a package comprising a package thermal conductor;
a thermally activated switch including:
a thermal electric cooler (TEC) including a first TEC surface thermally connected to the package thermal conductor, and a second TEC surface;
a thermally activated actuator (TAA); and
a thermal conductor (TC) including a TC surface;
the at least one device on and/or in the thermal conductor; and
a temperature compensation system on and/or in the thermal conductor, wherein the temperature compensation system includes at least one temperature sensor, a heater, and a processing circuitry, and wherein the at least one temperature sensor each of which is in the package or thermally coupled to the package thermal conductor, and wherein the at least one temperature sensor is configured to measure a first temperature that is a function of (x) a temperature of an interior environment in the package and/or (y) a temperature of the package;
wherein the processing circuitry is configured to cause the heater to heat the at least one device when the first temperature is below a first temperature threshold level and to not heat the at least one device when the first temperature is above the first temperature threshold level;
wherein the thermally activated switch is configured to (a) thermally couple the thermal conductor and the thermal electric cooler when the first temperature and/or a temperature of the thermally activated actuator exceeds a second temperature threshold level and (b) thermally decouple the thermal conductor and the thermal electric cooler when the first temperature and/or the temperature of the thermally activated actuator is less than the second temperature threshold level;
wherein the second temperature threshold level is greater than the first temperature threshold level.

2. The apparatus of claim 1, wherein the at least one device comprises at least one laser.

3. The apparatus of claim 1, wherein the apparatus is an atomic sensor;
wherein the at least one device comprises at least one of: at least one laser, at least one integrated circuit, at least one source of electromagnetic energy, a mechanical structure, an atomic reservoir, and optics.

4. The apparatus of claim 1, wherein the package further comprises a package thermal insulator partially or wholly covering an interior surface of the package thermal conductor.

5. The apparatus of claim 1, wherein the thermally activated actuator comprises at least one of a wax motor and a bimetallic strip;
wherein the thermally activated switch performs thermal coupling and thermal decoupling based on the temperature of the thermally activated actuator.

6. The apparatus of claim 1, wherein the processing circuitry is further configured to activate the thermal electric cooler when the thermally activated switch thermally couples the thermal conductor and the thermal electric cooler;
wherein the processing circuitry is further configured to deactivate the thermal electric cooler when the thermally activated switch thermally decouples the thermal conductor and the thermal electric cooler.

7. The apparatus of claim 1, wherein the thermally activated actuator comprises a first thermal conductor portion and a second thermal conductor portion which are thermally isolated from one another by a thermal insulator;
wherein the first thermal conductor portion is thermally coupled to the package thermal conductor;
wherein the second thermal conductor portion is configured to form a thermal connection between the TC surface and the second TEC surface.

8. A method for temperature stabilizing at least one device, the method comprising:
receiving a first temperature, wherein the first temperature is a function of (x) a temperature of an interior environment in a package and/or (y) a temperature of a package, wherein the package includes a package thermal conductor, and wherein the at least one device is on and/or in a thermal conductor;
determining whether the first temperature is less than a first temperature threshold level;
determining that the first temperature is less than the first temperature threshold level, then turning on a heater;
determining that the first temperature is greater than the first temperature threshold level, then:
turning off the heater;
thermally coupling the thermal conductor and a thermal electric cooler when the first temperature is greater than a second temperature threshold level, then, wherein a thermally activated switch includes:
the thermal electric cooler (TEC) including a first TEC surface thermally connected to the package thermal conductor, and a second TEC surface;
a thermally activated actuator (TAA); and
the thermal conductor (TC) including a TC surface; and
thermally decoupling the thermal conductor and the thermal electric cooler when the first temperature and/or the temperature of the thermally activated actuator is less than the second temperature threshold level;
wherein the second temperature threshold level is greater than the first temperature threshold level.

9. The method of claim 8, wherein thermally coupling the thermal conductor and the thermal electric cooler further comprises determining whether the first temperature is greater than the second temperature threshold level;
wherein the thermal coupling is only performed when the first temperature is greater than the second temperature threshold level.

10. The method of claim 8, wherein thermally decoupling the thermal conductor and the thermal electric cooler further comprises determining whether the first temperature is less than a third temperature threshold level;
wherein the thermal decoupling is only performed when the first temperature is less than the third temperature threshold level.

11. The method of claim 8, wherein turning off the heater comprises:
determining whether the heater is turned on;
wherein the heater is turned off only when the heater is determined to be turned on.

12. The method of claim 8, wherein the thermally activated actuator comprises at least one of a wax motor and a bimetallic strip;
wherein the thermal coupling and the thermal decoupling are performed based on the temperature of the thermally activated actuator.

13. The method of claim 8, wherein the thermally activated actuator comprises an electric motor;
wherein the thermal coupling and the thermal decoupling are performed based on the first temperature.

14. An apparatus for controlling a temperature of at least one component of an atomic sensor, the apparatus comprising:
a package comprising a package thermal conductor;
a thermal electric cooler (TEC) comprising a first TEC surface, thermally connected to the package thermal conductor, and a second TEC surface;
a thermally activated actuator (TAA);
a thermal conductor (TC) comprising a TC surface;
the at least one component on the thermal conductor; and
a heater on or in the thermal conductor and configured to heat the thermal conductor and the at least one component when a temperature of the thermal conductor and/or the temperature at least one of the at least one component falls below a first temperature threshold level;
wherein the thermally activated actuator is configured to change position based on a temperature of the thermally activated actuator to form a thermal connection between a surface of the thermal conductor and the second TEC surface when the temperature of the thermally activated actuator exceeds a second temperature threshold level so that the TEC cools the thermal conductor and the at least one component and to break off thermal contact between the surface of the thermal conductor and the second TEC surface when the temperature of the thermally activated actuator falls below a third temperature threshold level.

15. The apparatus of claim 14, wherein the at least one component consists of at least one laser.

16. The apparatus of claim 14, wherein the at least one component comprises at least one of: at least one laser, at least one integrated circuit, at least one source of electromagnetic energy, a mechanical structure, an atomic reservoir, and optics.

17. The apparatus of claim 14, wherein the package further comprises a thermal insulator in an interior of the package and surrounded by the package thermal conductor.

18. The apparatus of claim 14, wherein the thermally activated actuator comprises a first thermal conductor portion and a second thermal conductor portion which are thermally isolated from one another;
wherein the first thermal conductor portion is thermally coupled to the package thermal conductor;
wherein the package thermal conductor is exposed to exterior environmental temperature;
wherein the second thermal conductor portion is configured to form the thermal connection between the surface of the thermal conductor and the second TEC surface.

19. The apparatus of claim 14, wherein the thermally activated actuator comprises a motor;
wherein the thermally activated actuator is activated based on the temperature of the thermally activated actuator, and/or the temperature of the thermal conductor and/or the temperature of at least one of the at least one component.

20. The apparatus of claim 14, wherein the thermally activated actuator comprises at least one of a wax motor and a bimetallic strip;
wherein the thermally activated actuator is activated based on the temperature of the thermally activated actuator.
